(19) United States
(12) Patent Application Publication
(10) Pub. No.: US 2025/0378785 A1
(43) Pub. Date: Dec. 11, 2025

(54) PIXEL CIRCUIT AND CONTROL METHOD THEREOF, ELECTRONIC DEVICE, STORAGE MEDIUM AND PROGRAM PRODUCT

(71) Applicant: SEMICONDUCTOR INTEGRATED DISPLAY TECHNOLOGY CO., LTD., Wuhu City (CN)

(72) Inventors: Lin SUN, Wuhu City (CN); Shengfang LIU, Wuhu City (CN)

(21) Appl. No.: 19/095,726

(22) Filed: Mar. 31, 2025

(30) Foreign Application Priority Data
Jun. 8, 2024 (CN) 202410740348.8

(51) Int. Cl. G09G 3/3233

(52) U.S. Cl. CPC G09G 3/3233; G09G 2300/0819; G09G 2300/0852; G09G 2310/08; G09G 2320/0233

(57) ABSTRACT

The application discloses a pixel circuit and a control method thereof, an electronic device, a storage medium and a program product, which is suitable for Micro OLED, which can compensate for the difference in transistor threshold voltage characteristics between different pixels. The pixel circuit includes: a light-emitting circuit, a driving circuit, a compensation circuit and a switching circuit. The light-emitting circuit in the pixel circuit is in a light-emitting state before at least the pixel circuit is controlled to be in a discharge stage, and in the discharge stage, the substrate of the driving transistor can be discharged through the compensation circuit to compensate the substrate bias voltage of the driving transistor.

### CROSS-REFERENCE TO RELATED APPLICATIONS

This application is based on and claims priority under 35 U.S.C 119 to Chinese Patent Application No. 202410740348.8, filed on Jun. 8, 2024, in the China National Intellectual Property Administration. The entire disclosure of the above application is incorporated herein by reference.

### TECHNICAL FIELD

The disclosure herein relates to a technical field of display, especially to a pixel circuit and a control method thereof, an electronic device, a storage medium and a program product.

### BACKGROUND

Organic Light Emitting Diode (OLED) is one of the hot spots in the current flat panel display research field. Compared with liquid crystal displays, the OLED has the advantages of low energy consumption, low production cost, self-illumination, wide viewing angle and fast response speed, and has begun to replace the traditional liquid crystal display (LCD) in the field of flat panel displays such as mobile phones, PDAs, and digital cameras. Among them, the design of the driving circuit is the key technology to realize the display function.

### SUMMARY

The present disclosure provides a pixel circuit and a control method thereof, an electronic device, a storage medium and a program product, which is suitable for Micro OLED, which can compensate for the difference in transistor threshold voltage characteristics between different pixels, so that the display quality of the panel can be improved.

In the first aspect, the present disclosure provides a pixel circuit, including:
a light-emitting circuit connected to a driving circuit, and the light-emitting circuit being configured to emit light or to be turned off according to a driving current provided by the driving circuit;
the driving circuit including a driving transistor, and the driving transistor being connected to a data signal input end of the pixel circuit, a power input end and the light-emitting circuit; the driving circuit being configured to control the light-emitting circuit to emit light or to be turned off according to a signal input by the data signal input end;
a compensation circuit connected to the driving circuit and the power input end and the compensation circuit being configured to provide a compensation path for a turn-on threshold of the driving transistor;
a switch circuit connected to the driving circuit and the compensation circuit, and the switch circuit being configured to control connections between the driving transistor and the compensation circuit, the data signal input end and the power input end, so that each pole of the driving transistor comprises different potentials, and the pixel circuit is in different working phases;
the pixel circuit is configured to: be at least in a discharge phase before controlling the light-emitting circuit in the pixel circuit to be in a light-emitting state; in the discharge phase, a substrate of the driving transistor is discharged through the compensation circuit, thereby compensating a threshold voltage difference caused by a substrate bias voltage of the driving transistor.

In some embodiments, the switch circuit comprises a first transistor, a second transistor, a third transistor and a fourth transistor;
a gate of the driving transistor is connected to the data signal input end of the pixel circuit through a drain of the first transistor and a source of the first transistor, a source of the driving transistor is connected to the power input end through a drain of the second transistor and a source of the second transistor in turn, and a drain of the driving transistor is connected to an anode of the light-emitting diode through a source of the fourth transistor and a drain of the fourth transistor in turn;
a gate of the first transistor is configured to obtain a first control signal, and the first control signal is used for controlling turned-on and turned off of the first transistor;
a gate of the second transistor and a gate of the fourth transistor are configured to obtain a second control signal, and the second control signal is used for controlling turned-on and turned-off of the second transistor and the fourth transistor;
a source of the third transistor is connected to the drain of the driving transistor, a drain of the third transistor is grounded, a gate of the third transistor is configured to obtain a third control signal, and the third control signal is used for controlling turned-on and turned-off of the third transistor.

In some embodiments, the first control signal, the second control signal and the third control signal at least provide a turned-on signal and a turned-off signal respectively, so that the first transistor, the second transistor, the third transistor and the fourth transistor are respectively in a corresponding turned-on state and a corresponding turned-off state.

In some embodiments, the compensation circuit comprises a first capacitor and a second capacitor, the first capacitor and the second capacitor are sequentially connected in series between the gate of the driving transistor and the power input end, and an intermediate connection point of the first capacitor and the second capacitor is connected to the substrate of the driving transistor through the source of the driving transistor.

In some embodiments, the pixel circuit is configured to enter an initial phase through the switch circuit; in the initial phase, a gate voltage of the driving transistor rises to a first preset voltage, and a voltage difference of the gate and the source of the driving transistor satisfies a turned-on condition of the driving transistor.

In some embodiments, the pixel circuit is configured to be controlled to enter the initial phase through the switch circuit, by:
controlling the first control signal, the second control signal and the third control signal to provide the turned-on signal to control the first transistor, the second transistor, the third transistor and the fourth transistor to be in a turned-on state, and controlling the data signal input end to provide an initial voltage, thereby providing the first preset voltage to the gate of the driving transistor, so that the voltage difference of the gate and the source of the driving transistor satisfies the turned-on condition, and the source of the driving transistor is connected to the power input end and the compensation circuit, the drain of the driving transistor is connected to the light-emitting circuit through the fourth transistor, and is grounded through the third transistor.

In some embodiments, during the initial power-on, the pixel circuit is controlled to enter the initial phase until the gate voltage of the driving transistor reaches the first preset voltage, and the voltage difference of the gate and the source of the driving transistor satisfies the turned-on condition of the driving transistor.

In some embodiments, the pixel circuit is configured to be controlled to enter the discharge phase through the switch circuit; in the discharge phase, the substrate of the driving transistor is discharged to the compensation circuit through the source of the driving transistor, and the voltage difference of the gate and the source of the driving transistor changes until the driving transistor is in a turned-off state.

In some embodiments, the pixel circuit is configured to be controlled to enter the discharge phase through the switch circuit, by:
controlling the second control signal to provide a turned-off signal, the first control signal and the third control signal to provide a turned-on signal, to control the first transistor and third transistor to be turned on, the second transistor and fourth transistor to be turned off, and controlling the data signal input end to provide an initial voltage, and the initial voltage is used for make the driving transistor in a turned-on state in an initial phase; the substrate of the driving transistor is connected to the compensation circuit through the source of the driving transistor, and is discharged to the compensation circuit.

In some embodiments, in the initial phase, after the driving transistor is turned on, the pixel circuit is controlled to enter the discharge phase, and the discharge phase continues until the driving transistor is turned off.

In some embodiments, the pixel circuit is configured to be controlled to enter a third phase through the switch circuit after the discharge phase; in the third phase, the data signal input end provides a first data signal, and an amplitude of the first data signal is less than an amplitude of signal provided by the data signal input end in the discharge phase;
the gate of the driving transistor obtains the first data signal through the switch circuit, the substrate of the driving transistor is connected to the compensation circuit through the source of the driving transistor, and the drain of the driving transistor is suspended.

In some embodiments, the pixel circuit is controlled to enter the third phase through the switch circuit, by:
controlling a first control signal to provide a turned-on signal to control the first transistor to be turned on, and controlling a second control signal and a third control signal to provide a turned-off signal to control the second transistor, the third transistor and the fourth transistor to be turned off.

In some embodiments, the pixel circuit is configured to be controlled to enter a light-emitting phase through the switch circuit after the third phase; in the light-emitting phase, the gate of the driving transistor obtains a turned-on voltage and is in the turned-on state; the source of the driving transistor is connected to the power input end, and the compensation circuit, and the drain of the driving transistor is connected to the light-emitting circuit through a source of a fourth transistor and a drain of a fourth transistor.

In some embodiments, the pixel circuit is controlled to enter the light-emitting phase through the switch circuit, by:
controlling the second control signal to provide a turned-on signal, controlling the first control signal and the third control signal to provide a turned-off signal to control the second transistor and the fourth transistor to be turned on, and the first transistor and the third transistor are turned off.

In some embodiments, the pixel circuit controls the light-emitting circuit to be in a light-emitting state during the light-emitting phase; before entering the light-emitting phase, the pixel circuit is sequentially controlled to enter the initial phase and the discharge phase to control the driving transistor to be turned on, and after the driving transistor is turned on, the threshold voltage difference caused by the substrate bias voltage of the driving transistor is compensated.

In the second aspect, the present disclosure further provides a control method of a pixel circuit, being used for controlling the pixel circuit as mentioned above, and the control method includes followings:
before controlling the light-emitting circuit in the pixel circuit to be in a light-emitting state, at least controlling the pixel circuit to be in a discharge phase; in the discharge phase, the substrate of the driving transistor is discharged through the compensation circuit, thereby compensating for the threshold voltage difference caused by the substrate bias voltage of the driving transistor.

In some embodiments, before controlling the light-emitting circuit in the pixel circuit to be in the light-emitting state, the control method further includes:
controlling the driving transistor to be turned on through the switch circuit;
after the driving transistor is turned on, controlling the substrate of the driving transistor to discharge to the compensation circuit, thereby compensating for the threshold voltage difference caused by the substrate bias voltage of the driving transistor.

In some embodiments, the controlling the driving transistor to be turned on through the switch circuit, includes:
controlling a gate voltage of the driving transistor to rise to a first preset voltage through the switch circuit, and a voltage difference of a gate and a source of the driving transistor satisfies a turned-on condition of the driving transistor.

In some embodiments, the controlling the substrate of the driving transistor to discharge to the compensation circuit, includes:
controlling by the switch circuit, the substrate of the driving transistor to be connected to the compensation circuit through a source of the driving transistor, the control circuit discharges to the compensation circuit, and a voltage difference of a gate and the source of the driving transistor is changed until the driving transistor is turned off.

In some embodiments, after the at least controlling the pixel circuit to be in the discharge phase, includes:
providing, by the data signal input end, a first data signal, and an amplitude of the first data signal is less than an amplitude of a signal provided by the data signal input end in the discharge phase;
controlling, a transistor of the switch circuit between a gate of the driving transistor and the data signal input end to be turned on, the substrate of the driving transistor is connected to the compensation circuit through a source of the driving transistor, and a drain of the driving transistor is suspended.

In the third aspect, the present disclosure further provides an electronic device, including:
at least one processors
a memory configured to store an executable instruction;
the at least one processor is configured to invoke the executable instruction stored in the memory to implement the control method of claim 16.

In the fourth aspect, the present disclosure further provides a computer-readable storage medium storing a computer program instruction, wherein the control method as mentioned above is realized in response to the computer program instruction being executed by a processor.

In the fifth aspect, the present disclosure further provides a computer program product including a computer-readable code or a non-transitory computer-readable storage medium carrying a computer-readable code, in response to the computer-readable code being run in an electronic device, a processor in the electronic device implements the control method as mentioned above.

### BRIEF DESCRIPTION OF FIGURES

FIG. 1 is a schematic diagram of the structure of the pixel circuit in an embodiment of the present disclosure;

FIG. 2 is a schematic diagram of the pixel circuit in an embodiment of the present disclosure;

FIG. 3 is a timing diagram of each signal in the pixel circuit in an embodiment of the present disclosure.

### DETAILED DESCRIPTION

Illustrative embodiments of the present disclosure includes, but is not limited to, a pixel circuit and a control method thereof, an electronic device, a storage medium and a program product.

It is understood that, as used herein, the term “circuit” or “unit” may refer to or include application-specific integrated circuits (ASICs), electronic circuits, processing (shared, dedicated, or grouped) and/or memory that executes one or more software or firmware programs, combined logic circuits, and/or other appropriate hardware components that provide the functions described, or may be part of such hardware components.

It is understood that in each embodiment of the present disclosure, the pixel circuit and the control method thereof, the electronic device, the storage medium and the program product may be realized by a microprocessor, a digital signal processor, a microcontrol circuit, etc., and/or any combination thereof.

The driving circuit can generally include a scanning driving circuit, a light-emitting control circuit, a data driving circuit, a pixel circuit, etc., among which the pixel circuit design is the core technical content of OLED display, which has important research significance. With the development of display technology, people's requirements for display effects are getting higher and higher. However, in the existing display panels, the difference in transistor threshold voltage characteristics between different pixels leads to the problem of poor brightness uniformity of OLED displays, which affects the display effect.

The embodiments of the present disclosure are described in further detail below in conjunction with the accompanying drawings.

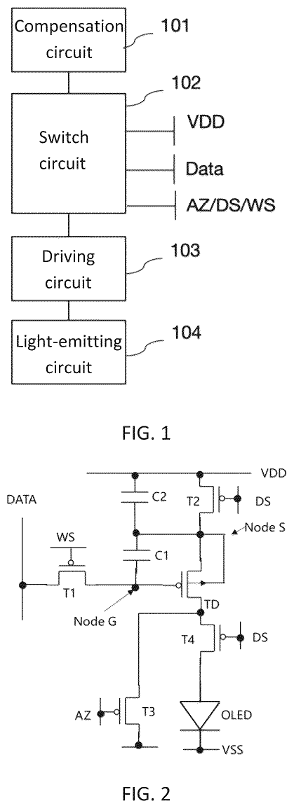

Refer to FIG. 1 for a schematic diagram of a structure of a pixel circuit in one of the embodiments of the present disclosure.

In this embodiment, the disclosure provides a pixel circuit including: a light-emitting circuit 104 connected to a driving circuit 103, and configured to emit light or to be turned off according to the driving current provided by the driving circuit 103; the driving circuit 103 includes a driving transistor, the driving transistor is connected to a data signal input end of the pixel circuit, the power input end and the light-emitting circuit 104, and is configured to control the light-emitting circuit 104 to emit light or to be turned off according to the signal input by the data signal input end; a compensation circuit 101 connected to the driving circuit 103 and the power input end and configured to provide a compensation path for the conduction threshold of the driving transistor; a switch circuit 102 connected to the driving circuit 103 and the compensation circuit 101, and the switch circuit 102 is configured to control the connection between the driving transistor and the compensation circuit 101, the data signal input end DATA, and the power input end VDD, so that each pole of the driving transistor has different potentials, to make the pixel mode circuit be in different working phases. The pixel circuit is configured to: before controlling the light-emitting circuit 104 in the pixel circuit to be in a light-emitting state, at least control the pixel circuit to be in a discharge phase. In the discharge phase, the substrate of the driving transistor can be discharged through the compensation circuit 101, thereby compensating the threshold voltage difference caused by the substrate bias voltage of the driving transistor.

In some embodiments, the switching circuit 102 includes a first transistor, a second transistor, a third transistor and a fourth transistor, and a driving transistor.

In some embodiments, the gate of the driving transistor is connected to the data signal input end of the pixel circuit through the drain of the first transistor and the source of the first transistor. The source of the driving transistor is connected to the power input end through the drain of the second transistor and the source of the second transistor in turn. The drain of the driving transistor is connected to the anode of the light-emitting diode through the source of the fourth transistor and the drain of the fourth transistor in turn. The gate of the first transistor is configured to obtain the first control signal WS. The first control signal WS is used for controlling the turned-on and turned-off of the first transistor. The gate of the second transistor and the gate of the fourth transistor are configured to obtain the second control signal DS. The second control signal DS is used for controlling the turned-on and the turned-off of the second transistor and the fourth transistor. The source of the third transistor is connected to the drain of the driving transistor, and the drain of the third transistor is grounded. The gate of the third transistor is configured to obtain the third control signal AZ. The third control signal AZ is used for controlling the turned-on and the turned-off of the third transistor.

In some embodiments, the first control signal, the second control signal and the third control signal can at least provide a turned-on signal and a turned-off signal respectively, so that the first transistor, the second transistor, the third transistor and the fourth transistor are respectively in a corresponding turned-on state or in a corresponding turned-off state.

In some embodiments, the compensation circuit 101 includes a first capacitor and a second capacitor. The first capacitor and the second capacitor are sequentially connected in series between the gate of the driving transistor and the power input end, and the intermediate connection point of the first capacitor and the second capacitor is connected to the substrate of the driving transistor through the source of the driving transistor.

In some embodiments, the pixel circuit is controlled to enter an initial phase through the switch circuit 102, and the gate voltage of the driving transistor is raised to the first preset voltage to be in a turned-on state in the initial phase.

In some embodiments, the controlling the pixel circuit to enter the initial phase through the switch circuit 102 includes: controlling the first control signal WS, the second control signal DS and the third control signal AZ to provide the turned-on signals so as to control the first, second, third and fourth transistors to be in the turned-on state, and controlling the data signal input end to provide an initial voltage so as to provide the first preset voltage to the gate of the driving transistor, so that the voltage difference of the gate and source of the driving transistor satisfies the turned-on requirement, the source of the driving transistor is connected to the power input end and the compensation circuit 101, the drain of the driving transistor is connected to the light-emitting circuit 104 through the fourth transistor, and the drain of the driving transistor is grounded through the third transistor.

In some embodiments, during the initial power-on, the pixel circuit is controlled to enter the initial phase until the gate voltage of the driving transistor reaches the first preset voltage, and the voltage difference of the gate and source of the driving transistor satisfies the turned-on condition of the driving transistor.

In some embodiments, the pixel circuit is controlled to enter the discharge phase through the switch circuit 102. In the discharge phase, the substrate of the driving transistor is discharged to the compensation circuit 101 through the source of the driving transistor, and the voltage difference of the gate and source of the driving transistor changes until the driving transistor is in a turned-off state.

In some embodiments, the controlling pixel circuit to enter the discharge phase through the switch circuit 102, includes: controlling the second control signal DS to provide a turned-off signal, controlling the first control signal WS and the third control signal AZ to provide a turned-on signal to control the first and third transistors to be turned on, the second and fourth transistors to be turned off, and controlling the data signal input end to provide an initial voltage which can make the driving transistor in a turned-on state in the initial phase. The substrate of the driving transistor is connected to the compensation circuit 101 through the source of the driving transistor, and discharges to the compensation circuit 101.

In some embodiments, in the initial phase, after the driving transistor is turned on, the pixel circuit is controlled to enter the discharge phase, and the discharge phase continues until the driving transistor is turned off.

In some embodiments, the pixel circuit is controlled to enter a third phase through the switch circuit 102 after the discharge phase. In the third phase, the data signal input end provides a first data signal. The amplitude of the first data signal is less than the amplitude of the signal provided by the data signal input end in the discharge phase. The gate of the driving transistor obtains the first data signal through the switch circuit 102. The substrate of the driving transistor is connected to the compensation circuit 101 through the source of the driving transistor, and the drain of the driving transistor is suspended.

In some embodiments, the controlling the pixel circuit to enter the third phase through the switch circuit 102, includes: controlling the first control signal WS to provide a turned-on signal to control the first transistor to be turned on, and controlling the second control signal DS and the third control signal AZ to provide a turned-off signal to control the second transistor, the third transistor and the fourth transistor to be turned off.

In some embodiments, the pixel circuit is configured as follows: after the third phase, the pixel circuit is controlled to enter the light-emitting phase through the switch circuit 102. In the light-emitting phase, the gate of the driving transistor obtains a turned-on voltage, and the driving transistor is in the turned-on state. The source of the driving transistor is connected to the power input end, and the compensation circuit 101. The drain of the driving transistor is connected to the light-emitting circuit 104 through the source and drain of the fourth transistor.

In some embodiments, the controlling the pixel circuit to enter the light-emitting phase through the switch circuit 102, includes: controlling the second control signal to provide a turned-on signal, controlling the first control signal and the third control signal to provide a turned-off signal to control the second transistor and the fourth transistor to be turned on, and the first transistor and the third transistor to be turned off.

In some embodiments, the pixel circuit controls the light-emitting circuit 104 to emit light during the light-emitting phase, and before the light-emitting circuit 104 is controlled to emit light, successively performing the initial phase and the discharge phase to control the driving transistor to be turned on, and compensating for the threshold deviation caused by the substrate bias effect after the driving transistor is turned on.

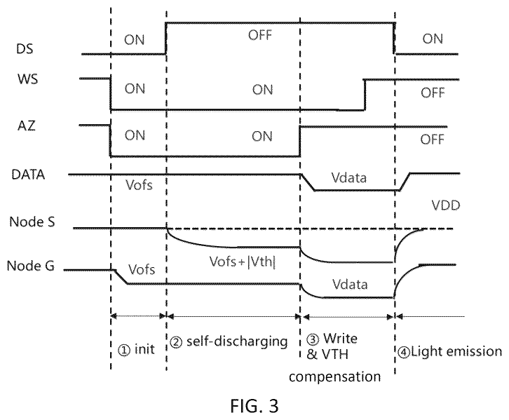

Refer to FIG. 2 and FIG. 3, where FIG. 2 is a schematic diagram of the pixel circuit in an embodiment of the present disclosure, and FIG. 3 is a timing diagram of each signal in the pixel circuit in an embodiment of the present disclosure.

In this embodiment, the pixel circuit includes 5T2C, that is, five transistors and two capacitors.

The source and drain of the first transistor T1 are respectively connected to the data trace and the gate (Node G) of the driving transistor TD. The upper and lower substrates of the first capacitor C1 are connected to the source and the gate of the driving transistor TD respectively. The upper and lower substrates of the second capacitor C2 are respectively connected to the power input end VDD and the source of the driving transistor TD. The source and the drain of the second transistor T2 are respectively connected to the power input end VDD and the source of the driving transistor TD. The source and the substrate of the driving transistor TD are shorted. The source and drain of the fourth transistor T4 are connected to the drain of the driving transistor TD and the anode of the OLED device, respectively. The source and drain of the third transistor T3 are connected to the drain of the driving transistor TD and VSS, respectively.

In this embodiment, the source and substrate of the driving transistor TD, the upper substrate of the first capacitor C1 and the lower substrate of the second capacitor C2, four nodes in total, are connected together.

Compared with the related art, this embodiment does not need to compensate the threshold voltage difference of each pixel by bias voltage, and can be applied to the threshold voltage regulation of the display panel of multiple pixels. Taking the panel of FHD level as an example, if the related art is adopted, the data signal of 1920*1080 is required as the bias voltage to adjust the threshold voltage difference of the driving transistor, and the data amount is large and complex, causing a certain control difficulty. The circuit in this embodiment, which is individually compensated for each pixel, can avoid problems in the related art.

In this embodiment, the pixel circuit includes the following phases when working.
(1) Initial phase: the first transistor T1, the second transistor T2, the third transistor T3 are all turned on, DATA=Vofs, and the Node G is initialized to Vofs, VDD−Vofs=Vinit>|Vth|, Vth is the threshold voltage of the driving transistor TD, and the Vofs can ensure that the driving transistor TD can be turned on during the discharge phase.
(2) Self-discharging phase, the second transistor T2, fourth transistor T4 are turned off, and the first transistor T1, third transistor T3 are turned on, and the voltage difference between the source and gate of the driving transistor TD gradually decreases as the Node S potential decreases, until the voltage difference is |Vth|; the driving transistor TD is turned off, the gate voltage of the driving transistor TD, Vg=Vofs, where Vofs is the voltage value of the initial signal input by the data signal input dend. The source voltage of the driving transistor TD, Vs=Vofs+|Vth|.
(3) The second transistor T2 and the third transistor T3 are turned off, and the voltage input by the data signal input end jumps from the initial voltage Vofs to the gray-scale voltage Vdata, ΔVg is the voltage change of the gate of the driving transistor TD, ΔVg=Vdata−Vofs, because the first capacitor C1 and the second capacitor C2 is connected in series, the voltage at the Node S is changed through the coupling of the first capacitor C1. ΔVs is the voltage change of the source of the driving transistor TD, ΔVs=(1−b)ΔVg, b=the second capacitor C2/(the first capacitor C1+the second capacitor C2), so Vs=Vofs+|Vth|+(1−b)*ΔVg=Vofs+|Vth|+(1−b) *(Vdata−Vofs), Vsg=Vs−Vg=Vofs+|Vth|+(1−b)*(Vdata−Vofs)-Vdata=|Vth|−b*Vdata+(2−b)Vofs.

In order to ensure that the driving transistor TD is turned on smoothly, the gray-level voltage Vdata can be set to be less than the initial voltage Vofs, and the 0-gray-level voltage can be set to a higher voltage separately. The 0-gray-level voltage refers to the corresponding data voltage when the screen is black.
(4) The first transistor T1 and the third transistor T3 are turned off, the second transistor T2 and the fourth transistor T4 are turned on, and the source voltage Vs of the driving transistor TD jumps to VDD, because the Node G is in the floating state, the voltage difference between the two ends of the first capacitor C1 remains unchanged, which is the same as that of phase (3), and the OLED emits light.

$$loled = {{β}^{*} [ V sg - \vert V th \vert ]}^{2} = {{β}^{*} [ ( V DD - V g ) - \vert V th \vert ]}^{2} = {{β}^{*} [ ( 2 - b ) V ofs - {b}^{*} Vdata ]}^{2} ;$$

Ioled is the current flowing through the light-emitting diode OLED; the β is constant and equals to 1/2*W/L*u*Cox, W/L is the aspect ratio of the driving transistor TD, u is the mobility, and Cox is the capacitance of TD. From the above formula, it can be seen that this the embodiments can fully compensate for the threshold voltage difference of the driving transistor TD, and is not affected by the substrate bias voltage and the threshold voltage difference.

In the second aspect, the present disclosure further provides a control method for a pixel circuit, including the following steps: before controlling the light-emitting circuit in the pixel circuit to be in a light-emitting state, at least controlling the pixel circuit to be in a discharge phase, and in the discharge phase, the substrate of the driving transistor can be discharged through the compensation circuit, thereby compensating the substrate bias voltage of the driving transistor.

In some embodiments, before controlling the light-emitting circuit in the pixel circuit to be in the light-emitting state, the method includes: controlling the driving transistor to be turned on through the switch circuit; after the driving transistor is turned on, controlling the substrate of the driving transistor to discharge to the compensation circuit, thereby compensating for the threshold voltage difference caused by the substrate bias voltage of the driving transistor.

In some embodiments, the controlling the driving transistor to be turned on through the switch circuit, includes: controlling the gate voltage of the driving transistor to rise to the first preset voltage through the switch circuit, and the gate source voltage difference of the driving transistor satisfies the turned-on condition of the driving transistor.

In some embodiments, the controlling the substrate of the driving transistor to discharge to the compensation circuit, includes: through the switch circuit, controlling the substrate of the driving transistor to connect with the compensation circuit through the source of the driving transistor, controlling the control circuit to discharge to the compensation circuit, and changing the voltage difference of the gate and source of the driving transistor until the driving transistor is turned off.

In some embodiments, after at least controlling the pixel circuit in the discharge phase, the method includes: providing by the data signal input end, a first data signal, and the amplitude of the first data signal is less than the amplitude of the signal provided by the data signal input end in the discharge phase; controlling the transistor of the switch circuit between the gate of the driving transistor and the data signal input end to be turned on; the substrate of the driving transistor is connected to the compensation circuit through the source of the driving transistor, and the drain of the driving transistor is suspended.

In the third aspect, the present disclosure further provides an electronic device including: one or more processors; a memory for storing executable instructions. The one or more processors is/are configured to invoke executable instructions stored in the memory to execute the method mentioned above.

In the fourth aspect, the present disclosure further provides a computer-readable storage medium on which computer program instructions are stored, and the method mentioned above is implemented when the computer program instructions are executed by a processor.

In the fifth aspect, the present disclosure further provides a computer program product, including computer-readable codes or a non-transitory computer-readable storage medium carrying computer-readable codes, whereby a processor in the electronic device performs the method mentioned above when the computer-readable codes are executed in the electronic device.

The pixel circuit of the present disclosure and the control method thereof, the electronic equipment, the storage medium and the program product can compensate the threshold voltage difference of the driving transistor, and is not affected by the substrate bias voltage of the driving transistor and the threshold voltage difference, and optimizes the brightness uniformity of the OLED display.

It is understood that the structure illustrated in the embodiments of the present disclosure does not constitute a specific limitation of the pixel circuit and the control method thereof, the electronic equipment, the storage medium and the program product. In other embodiments of the present disclosure. More or fewer parts may be included than illustrated, or certain parts may be combined, or certain parts may be disassembled, or different parts may be arranged. The illustrated parts can be implemented in hardware, software, or a combination of software and hardware.

Each embodiment of the mechanism disclosed in the present disclosure may be implemented in hardware, software, firmware, or a combination thereof. The embodiments of the present disclosure can be realized as a computer program or program code executed on a programmable system that includes at least one processor, a storage system (including transitory and non-transitory memory and/or storage elements), at least one input device, and at least one output device.

Program codes can be applied to input instructions to perform each function described in the present disclosure and to generate output information. The output information can be applied to one or more output devices in a known way.

The program codes can be implemented in a high-level programmatic language or a target-oriented programming language to communicate with the processing system. If required, the program code can also be implemented in assembly language or machine language. In fact, the mechanisms described in the present disclosure are not limited to the scope of any particular programming language. In either case, the language can be either a compiled language or an interpreted language.

In some cases, the disclosed embodiments may be implemented in hardware, firmware, software, or any combination thereof. The disclosed embodiments may also be implemented as instructions carried by or stored on one or more transient or non-transient machine-readable (e.g., computer-readable) storage media, which may be read and executed by one or more processors. For example, instructions can be distributed over a network or through other computer-readable media. Thus, machine-readable medium may include any mechanism used to store or transmit information in a machine (e.g., a computer) readable form, including, but not limited to, floppy disks, optical discs, optical discs, read-only memory (CD-ROMs), magneto-optical discs, read-only memory (ROM), random access memory (RAM), erasable programmable read-only memory (EPROM), electrically erasable programmable read-only memory (EEPROM), magnetic or optical cards, flash memory, or for electrical, optical, acoustic or other forms of propagating signals are tangible machine-readable memory for transmitting information (e.g., carrier, infrared, digital, etc.). Thus, machine-readable medium includes any type of machine-readable medium suitable for storing or transmitting electronic instructions or information in a machine-readable form, such as a computer.

In the drawings, some structural or methodological features can be shown in a specific arrangement and/or sequence. It should be understood, however, that such a specific arrangement and/or sequence may not be required. Rather, in some embodiments, the features may be arranged in a manner and/or sequence different from those shown in the illustrative drawings. In addition, the inclusion of structural or methodological features in a particular diagram does not imply that such features are required in all embodiments, and in some embodiments they may not be included or may be combined with other features.

It should be noted that each unit/circuit mentioned in the embodiments of each device in the present disclosure is a logical unit/circuit, and physically, a logical unit/circuit may be a physical unit/circuit or a part of a physical unit/circuit, and can also be realized in a combination of a plurality of physical units/circuits, the physical implementation mode of these logical units/circuits themselves is not the most important, and the combination of functions realized by these logical units/circuits is the key to solving the technical problems proposed in the present disclosure. In addition, in order to highlight the innovative part of the present disclosure, the above-mentioned device embodiments of the present disclosure do not introduce units/circuits that are not closely related to solving the technical problems raised in the present disclosure, which does not indicate that other units/circuits do not exist in the above-mentioned device embodiments.

It should be noted that in the examples and descriptions of this patent, relational terms such as “first” and “second”, etc., are used solely to distinguish one entity or operation from another, and do not necessarily require or imply the existence of any such actual relationship or sequence between those entities or operations. Further, the term “including”, “containing” or any other variation thereof is intended to cover non-exclusive inclusion so that a process, process, article or apparatus that includes a series of elements includes not only those elements, but also other elements that are not expressly listed, or that are inherent to such process, method, article or apparatus. In the absence of further restrictions, the element qualified by the phrase “including one” does not preclude the existence of another identical element in the process, method, article or apparatus that includes said element.

Although the present disclosure has been illustrated and described by reference to some preferred embodiments of the present disclosure, it should be understood by those of ordinary skill in the art that various changes may be made to it in form and detail without deviating from the spirit and scope of the present disclosure.

What is claimed is:

1. A pixel circuit, comprising:
a light-emitting circuit connected to a driving circuit, wherein the light-emitting circuit is configured to emit light or to be turned off according to a driving current provided by the driving circuit;
the driving circuit comprising a driving transistor, wherein the driving transistor is connected to a data signal input end of the pixel circuit, a power input end and the light-emitting circuit; and the driving transistor is configured to control the light-emitting circuit to emit light or to be turned off according to a signal input by the data signal input end;
a compensation circuit connected to the driving circuit and the power input end, wherein the compensation circuit is configured to provide a compensation path for a turn-on threshold of the driving transistor;
a switch circuit connected to the driving circuit and the compensation circuit, wherein the switch circuit is configured to control connections of the driving transistor with the compensation circuit, the data signal input end and the power input end, to provide each pole of the driving transistor with different potentials for controlling the pixel circuit to be in different working phases;
wherein the pixel circuit is configured to: be at least in a discharge phase before the light-emitting circuit in the pixel circuit is controlled to be in a light-emitting state; in the discharge phase, a substrate of the driving transistor is discharged through the compensation circuit to compensate a threshold voltage difference caused by a substrate bias voltage of the driving transistor.

2. The pixel circuit according to claim 1, wherein the switch circuit comprises a first transistor, a second transistor, a third transistor and a fourth transistor, the light-emitting circuit comprises a light-emitting diode, wherein:
a gate of the driving transistor is connected to the data signal input end of the pixel circuit through a drain of the first transistor and a source of the first transistor; a source of the driving transistor is connected to the power input end through a drain of the second transistor and a source of the second transistor in turn; and a drain of the driving transistor is connected to an anode of the light-emitting diode through a source of the fourth transistor and a drain of the fourth transistor in turn;
a gate of the first transistor is configured to obtain a first control signal, and the first control signal is used for controlling turned-on and turned-off of the first transistor;
a gate of the second transistor and a gate of the fourth transistor are configured to obtain a second control signal, and the second control signal is used for controlling turned-on and turned-off of the second transistor and the fourth transistor;
a source of the third transistor is connected to the drain of the driving transistor, a drain of the third transistor is grounded, a gate of the third transistor is configured to obtain a third control signal, and the third control signal is used for controlling turned-on and turned-off of the third transistor.

3. The pixel circuit according to claim 2, wherein the first control signal, the second control signal and the third control signal at least provide a turned-on signal and a turned-off signal respectively to control the first transistor, the second transistor, the third transistor and the fourth transistor to be respectively in a corresponding turned-on state and a corresponding turned-off state.

4. The pixel circuit according to claim 1, wherein the compensation circuit comprises a first capacitor and a second capacitor, the first capacitor and the second capacitor are sequentially connected in series between a gate of the driving transistor and the power input end, and an intermediate connection point of the first capacitor and the second capacitor is connected to the substrate of the driving transistor through a source of the driving transistor.

5. The pixel circuit according to claim 1, wherein the pixel circuit is configured to be controlled to enter an initial phase through the switch circuit; in the initial phase, a voltage of a gate of the driving transistor rises to a first preset voltage, and a voltage difference of the gate and a source of the driving transistor satisfies a turned-on condition of the driving transistor.

6. The pixel circuit according to claim 3, wherein the pixel circuit is configured to be controlled to enter the initial phase through the switch circuit, by:
controlling the first control signal, the second control signal and the third control signal to provide the turned-on signal to control the first transistor, the second transistor, the third transistor and the fourth transistor to be in a turned-on state, and controlling the data signal input end to provide an initial voltage, thereby providing the first preset voltage to the gate of the driving transistor, so that the voltage difference of the gate and the source of the driving transistor satisfies the turned-on condition, the source of the driving transistor is connected to the power input end and the compensation circuit, the drain of the driving transistor is connected to the light-emitting circuit through the fourth transistor and is grounded through the third transistor.

7. The pixel circuit according to claim 5, wherein during initial power-on, the pixel circuit is controlled to enter the initial phase until the voltage of the gate of the driving transistor reaches the first preset voltage, and the voltage difference of the gate and the source of the driving transistor satisfies the turned-on condition of the driving transistor.

8. The pixel circuit according to claim 2, wherein the pixel circuit is configured to be controlled to enter the discharge phase through the switch circuit; in the discharge phase, the substrate of the driving transistor is discharged to the compensation circuit through a source of the driving transistor, and a voltage difference of a gate and the source of the driving transistor changes until the driving transistor is in a turned-off state.

9. The pixel circuit according to claim 8, wherein the pixel circuit is configured to be controlled to enter the discharge phase through the switch circuit, by:
controlling the second control signal to provide a turned-off signal, the first control signal and the third control signal to provide a turned-on signal, to control the first transistor and third transistor to be turned on, and the second transistor and fourth transistor to be turned off, and controlling the data signal input end to provide an initial voltage;
wherein the initial voltage is used for making the driving transistor in a turned-on state in an initial phase; the substrate of the driving transistor is connected to the compensation circuit through the source of the driving transistor, and is discharged to the compensation circuit.

10. The pixel circuit according to claim 5, wherein in the initial phase, after the driving transistor is turned on, the pixel circuit is controlled to enter the discharge phase, and the discharge phase continues until the driving transistor is turned off.

11. The pixel circuit according to claim 2, wherein the pixel circuit is configured to be controlled to enter a third phase through the switch circuit after the discharge phase; in the third phase, the data signal input end provides a first data signal, and an amplitude of the first data signal is less than an amplitude of signal provided by the data signal input end in the discharge phase;
a gate of the driving transistor obtains the first data signal through the switch circuit, the substrate of the driving transistor is connected to the compensation circuit through a source of the driving transistor, and a drain of the driving transistor is suspended.

12. The pixel circuit according to claim 11, wherein the pixel circuit is controlled to enter the third phase through the switch circuit, by:
controlling the first control signal to provide a turned-on signal to control the first transistor to be turned on, and controlling a second control signal and a third control signal to provide a turned-off signal to control the second transistor, the third transistor and the fourth transistor to be turned off.

13. The pixel circuit according to claim 11, wherein the pixel circuit is configured to be controlled to enter a light-emitting phase through the switch circuit after the third phase; in the light-emitting phase, the gate of the driving transistor obtains a turned-on voltage and is in the turned-on state; a source of the driving transistor is connected to the power input end and the compensation circuit, and the drain of the driving transistor is connected to the light-emitting circuit through a source and a drain of a fourth transistor.

14. The pixel circuit according to claim 13, wherein the pixel circuit is controlled to enter the light-emitting phase through the switch circuit, by:
controlling the second control signal to provide a turned-on signal, controlling the first control signal and the third control signal to provide a turned-off signal to control the second transistor and the fourth transistor to be turned on, and the first transistor and the third transistor to be turned off.

15. The pixel circuit according to claim 13, wherein the pixel circuit controls the light-emitting circuit to be in a light-emitting state during the light-emitting phase; before entering the light-emitting phase, the pixel circuit is sequentially controlled to enter the initial phase and the discharge phase to control the driving transistor to be turned on, and after the driving transistor is turned on, the threshold voltage difference caused by the substrate bias voltage of the driving transistor is compensated.

16. A control method of a pixel circuit, being used for controlling the pixel circuit as claimed in claim 1, and the control method comprises:
before controlling the light-emitting circuit in the pixel circuit to be in a light-emitting state, at least controlling the pixel circuit to be in a discharge phase;
wherein in the discharge phase, the substrate of the driving transistor is discharged through the compensation circuit, thereby compensating the threshold voltage difference caused by the substrate bias voltage of the driving transistor.

17. The control method of the pixel circuit according to claim 16, wherein before controlling the light-emitting circuit in the pixel circuit to be in the light-emitting state, the control method further comprises:
controlling the driving transistor to be turned on through the switch circuit;
after the driving transistor is turned on, controlling the substrate of the driving transistor to discharge to the compensation circuit, thereby compensating the threshold voltage difference caused by the substrate bias voltage of the driving transistor.

18. The control method of the pixel circuit according to claim 16, wherein the controlling the driving transistor to be turned on through the switch circuit, comprises:
controlling a voltage of a gate of the driving transistor to rise to a first preset voltage through the switch circuit, and controlling a voltage difference of the gate and a source of the driving transistor to satisfy a turned-on condition of the driving transistor.

19. The control method of the pixel circuit according to claim 16, wherein the controlling the substrate of the driving transistor to discharge to the compensation circuit, comprises:
controlling by the switch circuit, the substrate of the driving transistor to be connected to the compensation circuit through a source of the driving transistor, controlling the control circuit to discharge to the compensation circuit, and controlling a voltage difference of a gate and the source of the driving transistor to be changed until the driving transistor is turned off.

20. The control method of the pixel circuit according to claim 16, wherein after the at least controlling the pixel circuit to be in the discharge phase, the control method further comprises:
providing, by the data signal input end, a first data signal, wherein an amplitude of the first data signal is less than an amplitude of a signal provided by the data signal input end in the discharge phase;
controlling, a transistor of the switch circuit between a gate of the driving transistor and the data signal input end to be turned on, controlling the substrate of the driving transistor to be connected to the compensation circuit through a source of the driving transistor, and controlling a drain of the driving transistor to be suspended.
